(19) United States
(12) Patent Application Publication
(10) Pub. No.: US 2010/0294347 A1
(43) Pub. Date: Nov. 25, 2010

(54) METHOD AND MEANS FOR CONNECTING THIN METAL LAYERS

(75) Inventors: Klaus Zimmer, Parthenstein (DE); Alexander Braun, Leipzig (DE); Karsten Otte, Leipzig (DE); Lothar Gerlach, Oegstgeest (NL)

Correspondence Address: OLIFF & BERRIDGE, PLC, P.O. BOX 320850, ALEXANDRIA, VA, 22320-4850, US

(73) Assignee: EUROPEAN SPACE AGENCY, PARIS (FR)

(21) Appl. No.: 12/734,523

(22) PCT Filed: Nov. 5, 2008
(86) PCT No.: PCT/EP2008/009316

§ 371 Date: Jul. 21, 2010

(30) Foreign Application Priority Data
Nov. 7, 2007 (DE) 10 2007 052 972.6

(51) Int. Cl. H01L 31/00; H05K 1/00; B23K 26/00

(52) U.S. Cl. 136/252; 174/254; 219/121.85

(57) ABSTRACT

A configuration and method for bonding a thin metal layer to two workpieces, e.g. solar cells and film-backed/reinforced small contact strips including: (i) the backing film is removed from the solar cell; (ii) the two films/layers are pressed together; and (iii) the two parts are irradiated from the side of the rear contact of the thin-film solar cell. Preferably two or three laser treatment steps are used for removing the backing film of the thin-film solar cell in an ablation process by means of a short-pulse laser and riveting the first metal layer to the second metal layer by irradiating the same by means of a long-pulse laser.

The present invention relates to an arrangement for bonding two metal layers applied to flexible substrates and a method for implementing such connection. In particular, the invention relates to the electric connection of thin-film solar cells to flexible circuit boards and a method for manufacturing the same.

Currently, different types of thin-film solar cells converting sunlight to electrical energy are being developed. FIG. 1 shows the schematic structure of such a cell which substantially consists of a front contact {5}, a rear contact {2} and a semiconducting absorber layer {3}. The front contact faces the incoming light and consists of a transparent conductive oxide (TOC), the rear contact consists of a metal layer. The light converting semiconductor layer (absorber) {3} may consist of different materials, for example, amorphous and microcrystalline or polycrystalline silicon, copper indium gallium diselenide (CIGS) and other semiconducting materials. An additional thin semiconducting film {4} having opposite conductivity is required for producing the p-n-junction with the semiconducting absorber layer {3}. For GIGS solar cells, the p-n-junction is formed by a heterojunction of the GIGS layer and a thin CdS layer.

The manufacture of thin solar cells on flexible substrates has already been disclosed or presented (Literature Alex). Polymers offer exquisite characteristics, such as, for example, strength, density, surface quality etc. at a low weight. However, the maximum service temperature is limited because of the stability of the polymer material. Yet, an additional energy input in the form of thermal energy or radiation is necessary for a qualitatively high-grade semiconductor layer deposition. For this reason, high performance polymer films, such as, for example, Kapton®, are used for the industrial process of depositing thin semiconductor layers for flexible solar cells.

These materials are also used with or without textile reinforcement for rigid and flexible circuit boards. The technology of the manufacture of both the basic material and different products is known.

The electrical energy produced in the solar cell has to be delivered on to the consumer. For this purpose, the thin layers have to be electrically contacted and connected to a conductor layer system. In the case of thin-film solar cells and particularly of flexible solar cells, this contact also has to be flexible so that thin layers, thin films or similar thin metallic conductors should be used as well.

A standard process for connecting the contact pads of massive solar cells, such as, for example, silicon wafer solar cells, is the soldering of contact strips to soldering points of front and rear contacts, for example, by radiation with high performance lamps. The soldering of thin layers is more complicated due to the low layer thickness of approximately 1 pm and less. It is known that the alloy processes occurring during the soldering may cause damage to the thin layers or contact points.

Another method of connecting thin-film solar cells to the external contacts is the use of contact adhesives. This widely spread process, however, requires the use of an additional material. Due to the specific resistance values of the contact adhesive and the usual application techniques of the pastes, for example, silk-screen printing or similar methods, the contact area should be of medium size.

Furthermore, connecting technologies are known which get by without additional materials such as conductive adhesive or brazing solder. The connection of thin wires to semiconductor chips is known from semiconductor industry and implemented by a so-called bonding process. However, this process requires special surfaces and materials and can only be carried out using special metals such as gold and aluminum. Moreover, high pressures act on the surface of the thin layers during bonding. The mechanical rigidity of the polymer films does not correspond to the requirements of the bonding process as used in semiconductor industry.

Modern laser technology provides powerful laser sources having performances in the kW range. Engineering applications require such performances, however, as a rule, a few watts are sufficient for micro processes. Furthermore, the laser beam may be focused to very small areas and guided to arbitrary points on the surface in a controlled manner. The splitting of powerful laser beams in partial beams is often used to increase performance, speed and treatment quality, respectively.

JP2005191584 presents an integrated solar battery in which terminal pads tap the voltage of the solar cell. In order to connect the solar battery to a tin-plated copper film, brazing solder was additionally applied to the bonding spots. Thus, it is possible to implement the contacting by a soldering process.

Laser beam machining is regularly used for solar cell production. Particularly in the manufacture of thin-film solar cells, laser scoring is used in order to insulate the different parts of the solar cell from each other. Such scoring methods are also used for the serial wiring of solar cells, as illustrated in EP 1 727 211.

Another concept of the connection of thin-film solar cells to an external contact is disclosed by E. J. Simburger et al. in “Development of a thin film solar cell interconnect for the PowerSphere concept”, Materials Science and Engineering Vol 116 (2005) 321-325, and similarly illustrated in U.S. 20050011551. The concept is based on the use of an encompassing edge contact disposed at the edge of a thin-film solar cell for establishing electric connections between the layers of a thin-film solar cell and the contact pads disposed on the rear side of the solar cell. A laser beam is used to weld the copper film to flexible small contact strips. In this embodiment, the encompassing edge contact has to be produced by a complicated sequence of thin-film coating processes. Furthermore, the connection of the encompassing contact to the external small contact strip is established by laser welding. On the basis of the metals used, a metal junction contact is formed which is typical of the formation of alloys occurring while the liquid phases mix during welding.

U.S. Pat. No. 6,114,185 discloses to use laser welding for connecting semiconductor components to metal parts. However, a contact to the electrodes of the solar cell is not provided. Furthermore, emphasis is placed on the fact that the semiconductor components have to withstand the temperatures during the welding process.

The currently available laser technologies enable the connection of metal parts by laser irradiation. Typical processes are welding and soldering with and without additional materials. For a reliable connection, diffusion processes bring about the mixing of the metals and may lead to the formation of additional phases. If different metals are connected by thermal or laser processes, problems may arise due to the different phase junction temperatures, insufficient formation of alloys or the dissolution of the thin layers during the treatment in a liquid/molten state.

The currently available methods for connecting thin layers to the exterior wiring have disadvantages. For establishing the connection, they either require high technical, procedural or technological efforts, special materials or specific surfaces. Particularly in the case of flexible substrates, these aspects become especially important.

It is the object of the invention to provide a novel method for connecting thin metal layers on flexible substrates which enables a connection of the thin layer to the exterior wiring with little effort and little space required. It is particularly intended to provide a reliable method for connecting at least two metal layers that make it possible to mechanically and electrically bond preferably two different materials.

According to the invention, the object is achieved by the application of pulsed laser radiation in accordance with the features mentioned in claim 1. The present invention provides a process for micro riveting thin layers and films, which enables the mechanic and electric connection of thin metal layers by geometrically interlocking the materials and the formation of mixtures of the involved materials. In addition, a method for manufacturing such micro riveted joints for thin layers and films is provided.

The present invention shows a configuration for micro bonding two thin layers or two thin-film staples by means of micro (hollow) rivets preferably consisting of the material of one of the two involved thin layers, and a process for micro riveting such thin layers or thin-film staples by laser radiation.

The objects, characteristics, aspects and advantages of the present invention are clarified by means of the following detailed description of the invention together with the attached Figures.

### DESCRIPTION OF THE FIGURES

FIG. 1: Schematic view of the basic structure of a thin-film solar cell on flexible substrates.

FIG. 2: 3D scheme of the area of bonding of a solar cell with the small contact strip by means of micro riveting.

FIG. 3: The most important process steps for laser riveting or laser bonding are schematically shown.

FIG. 4: Examples for different embodiments of laser rivet connections using the example of a connection of a thin-film solar cell to a flexible connecting line.

FIG. 5: Example for the use of laser rivets for connecting the front and rear contact of a solar cell to a flexible connecting line.

FIG. 6: Schematic view of the current flow when connecting the front and rear contact of a solar cell to a flexible connecting line system.

FIG. 7: REM illustration of a laser riveting process between a flexible copper circuit board and a thin-film solar cell on a Kapton film.

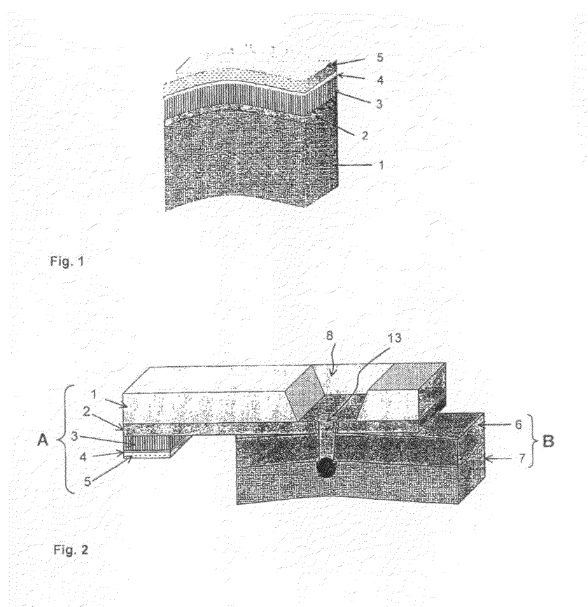

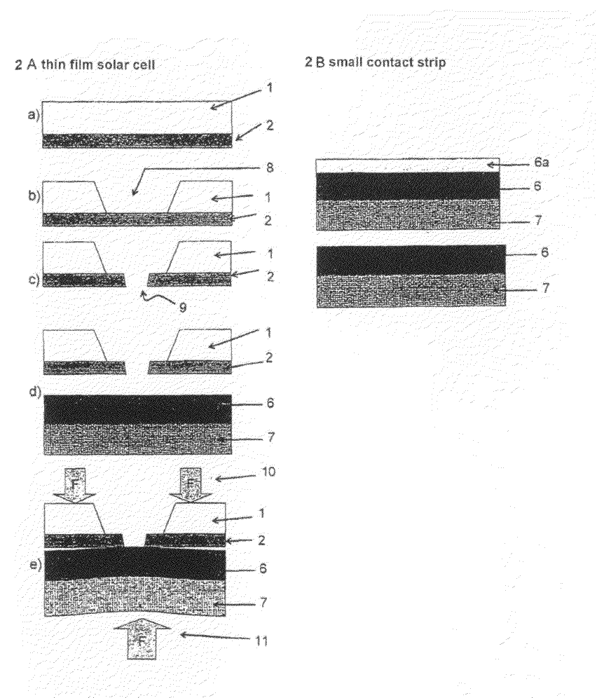

Below, the invention will be described in more detail by using the embodiments illustrated in the drawings. In the Figures, identical symbols (numerals, abbreviations, names etc.) denote identical or congenial components or processes.

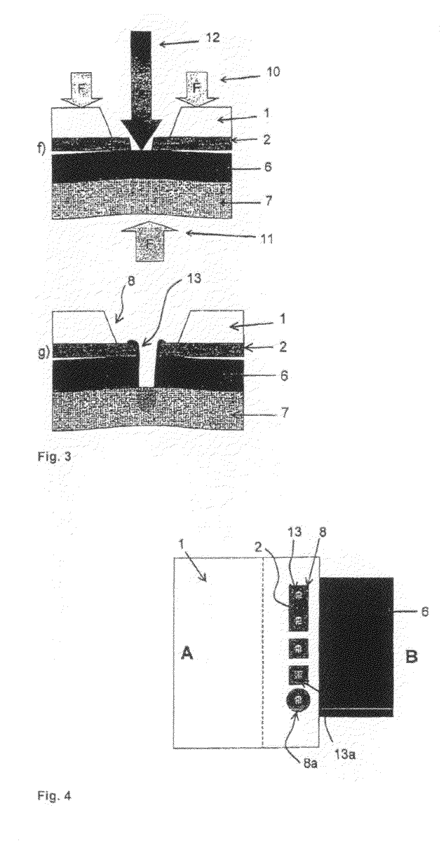

FIGS. 3 a) to g) schematically illustrate the major steps for bonding thin-film structures by means of laser riveting in a preferred embodiment of the present invention for bonding thin-film solar cells to a flexible electric connecting line.

As shown in FIG. 3 a), at first the top layers of the solar cell (in particular the front contact and the absorber layer) are removed to expose the thin-film rear contact {2}, which in this case consists of molybdenum. Furthermore, the polymer backing film {1} is removed in a defined area {8} down to the thin metal layer {2} as shown in FIG. 3 b). This may be done by ablation using a pulsed UV laser whose pulse duration is less than 1 μs. The laser ablation parameters, for example the laser fluence, are selected such that the ablation of the backing film {1} can be implemented such that the non-destructive removal of the backing film material from the thin metal layer {2} is possible so that the manufacture of a thin metal layer now exposed is ensured. Analogue processes may be used for preparing the contact area of the flexible connecting line. The cover layers {6a} etc. in particular, for example a possible cover layer of the contact metal, have to be removed at least in the area where the laser riveting is to be performed.

In a particular embodiment of the process, as shown in FIG. 3 c), a small hole is drilled in the thin metal layer of the rear contact. This drilling process is preferably performed after the polymer ablation of the backing film of the solar cell according to FIG. 3 b), however, it may also be performed thereafter. In both embodiments, a sufficiently exact overlapping precision is required in the process steps in order to ensure that the drilled metal hole {9} is within the ablated area {8}. This will be guaranteed in particular when for both process steps the same system or even the same laser beam is used. A combination of the laser ablation of the backing film {1} and the metal layer {2} by using the same laser beam, even if different laser parameters are used, if required, may improve the production as to speed and functional safety. The process steps illustrated in FIGS. 3 b) to c) may also be performed if the flexible connecting line already supports the solar cell film, as shown in FIG. 3 d).

In the next step, see FIG. 3 e), the thus prepared area of the thin-film solar cell is pressed onto the flexible connecting line. In this step, forces {10, 11} are applied to the thin-film solar cell and the flexible connecting line {7} in order to sufficiently reduce the distance between both metal layer surfaces.

Now the thin metal rear contact of the thin-film solar cell is in contact with the metal of the flexible connecting line. Both metals {2, 6} are connected by laser radiation {12} as shown in FIG. 3 f). To this end, pulsed laser radiation having pulse durations of more than 1 μs is preferably used. The wavelength may be selected in accordance with the requirements. However, for reasons of cost, an Nd:YAG laser having a wavelength of 1.06 pm is preferred. Due to the laser radiation and the thus triggered processes a connection mechanically connecting both metal layers to each other and also forming an electric contact is created which in cross-section resembles a rivet connection. After the forces that pressed both parts upon each other have been disengaged, a stable laser rivet connection {13} has been created, as schematically shown in FIG. 3g).

For stably and reproducibly bonding a thin-film solar cell to a flexible connecting line, usually a plurality of micro rivets are desirable, as shown in FIG. 4. The Figure shows different possibilities of the configuration of micro rivets and the opened rear contact as to shape, design and size. Other shapes, configurations and sizes are also possible. The rivets may also be slit-shaped. Individual laser riveting joints may be arranged in rows or form a dense arrangement.

In order to achieve qualitatively high-grade rivet connections, both metal surfaces must be as close to each other as possible during the laser riveting process. In order to achieve this, the following methods may be applied or combined with each other: Vacuum tables, pressure of a gas stream or the use of the pressure of the ablation cloud. Furthermore, the films may be guided over arcuate workpiece supports, e. g. rolls. Other technical means are also possible.

A hole drilled in the upper metal layer supports the formation of micro rivets especially for laser riveting different materials. This hole may be placed at different states of the production process. Preferably, however, a laser will be used, with different laser types being usable. Without a doubt the laser used for riveting may also be used for drilling. The optimal temporal energy supply therefor may be performed by controlling the output performance or the pulse duration of the laser beam. A refined method is the modification of the pulse duration by suitable means, for example electro-optical members. An embodiment which is also preferred is the electric control of the laser output performance. It is possible to perform the drilling and laser riveting process with a laser by including such control methods. A variation of the pulse duration may also be preferable in order to both drill and weld with one and the same laser. Likewise, a suitable control of the pulse form of the laser is possible in order to drill and weld with the same laser.

In order to simultaneously create a series of micro rivets, the laser beam may be split and thus be multiply used for the laser riveting process at the same time. Consequently, a row of rivet connections can simultaneously be created.

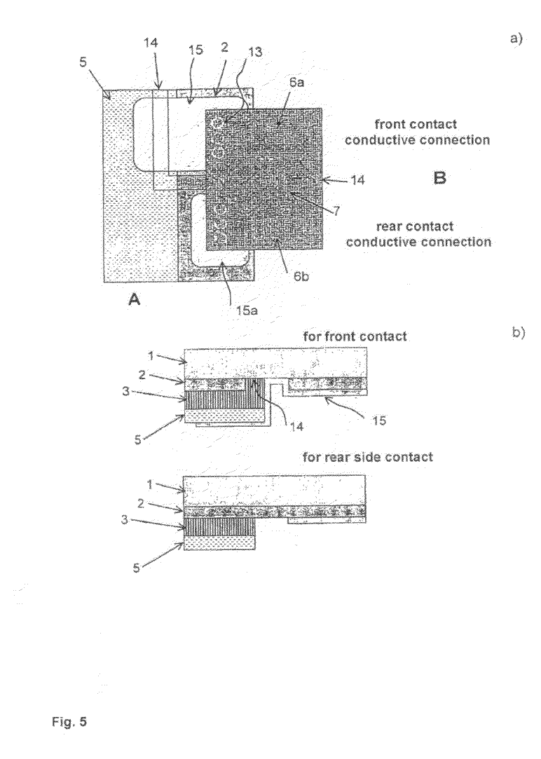

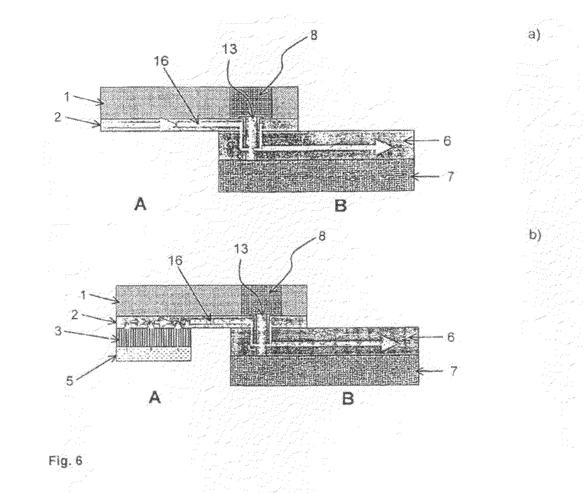

The application of the laser riveting method for contacting thin-film solar cells is schematically shown in FIG. 5. The scheme shows the top view of the bonded area, the front contact lying on top. As an example for practical application, the rear side and the front contacts were both simultaneously connected to the small contact strip. Therefore, additional process steps had to be inserted before the laser riveting process at different states of the production of the solar cell {A} and the flexible electric connecting line {B}. At first, the rear contact of the solar cell {2} has to be scored for safe electrical insulation from the parts of the rear contact provided for bonding with the front contact. Additionally, the metal layer {6} of the flexible electric connecting line {B} has to be scored such that two lines {6a} and {6b} are created.

The scorings are denoted by {14}. In order to connect the front contact to the insulated rear side area, an additional metal layer {15}, for example, was applied. This electric connection can also be made alternatively, for example by a conductive adhesive. The metal layer {15} may also be positioned on the surface of the rear contact layer {2} whereby the laser riveting process may be improved. Accordingly, a careful selection of the metal layer {15} is required. The cross sections of the front and rear contacts of the solar cell prepared for bonding are schematically shown in FIG. 5b). Now the laser riveting process may be performed in the manner described above. In order to increase the strength of the bonding point, several rivets may be mounted.

FIG. 6 schematically illustrates the current flow from a first thin metal layer, for example a solar cell, to a second metal layer, for example a flexible electric connecting line. The laser riveting processes are performed in a manner similar to those described. With respect to the electric bonding, laser rivets enable the current flow between two thin flexible substrates coated with two different metals. Furthermore, the laser rivets also achieve a mechanic connection and can also be used only for this purpose.

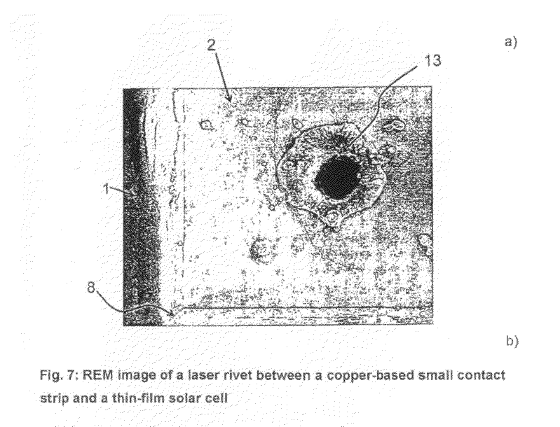

The REM image in FIG. 7 shows a laser rivet connection between the rear contact of a thin-film solar cell and the copper coating of a flexible circuit board. The metal of the rear contact is molybdenum which is neither easy to solder nor to weld. On the left and the lower side of the Figure, the edges of the opened backing film are visible. In the proximity of the center, material thrown out around the entire hole is visible, which material is generated during the laser riveting process and, having resolidified from the liquid state, forms the rivet.

### EXAMPLES OF APPLICATION

The present invention will now be described in more detail by using various examples.

### First Example

The present invention will now be described more concretely by means of the riveting process of a thin molybdenum film to a flexible small copper contact strip. Such thin molybdenum layers are used for rear contacts for solar cells, for example GIGS solar cells, as shown in FIG. 1. For the riveting process, the top layers of the solar cell as a front contact, absorber etc. may be removed mechanically or by using a laser down to the rear contact in order to expose the molybdenum layer, as shown in FIG. 3 a).

The polymer backing film is removed from the thus prepared solar cell by means of laser ablation. In order to perform this, the solar cell front is closely connected to a stable retainer in the area of the rear ablation of the polymer backing film and irradiated by a laser of sufficient pulse energy. In order to gently ablate the polymer film (UPILEX ??? Alex(SOLARION) thickness approx. 25 μm), a UV laser beam having a wavelength <300 nm is used. The energy density of the ablating laser beam is reduced to the rear contact during the continuing ablation while the ablation depth increases and the remaining thickness of the film is reduced in order to ensure a selective ablation of the polymer substrate to the metallic rear contact. In this example, an Excimer laser having a wavelength of 248 nm and a laser fluence of 200 to 600 mJ/cm² is used. For a selective local removal of the polymer layer, alternative processes such as plasma etching may be applied.

It should be noted that a small hole in the highly melting molybdenum layer can support and improve the laser riveting process. To this end, a small hole is drilled in the molybdenum layer, as shown in FIG. 3c), after the ablation of the polymer film supporting the solar cell. The hole will later support the formation of the laser rivet. In this example, the hole was drilled in the molybdenum rear contact having a thickness of 5 μm within 0.1 s using an ultra short pulse laser radiation at a wavelength of 775 nm and a fluence of 3 J/cm². Due to the ultra-short laser pulse, there is almost no melting of the thin metal layer outside of the hole so that an edge bead can be avoided. The size of the hole was selected to be slightly smaller than the size of the laser beam used for the laser riveting process. In this example, a laser spot of approx. 15 μm was used. The matching drill hole size can be adjusted on the metal layer to be drilled by circular movements of the laser spot. However, although the hole was drilled after the ablation of the polymer backing film in this example, it may also be generated beforehand.

A flexible connecting line consisting of a 25 μm thick copper layer on a Kapton® backing film (d˜50 μm) was used for the laser riveting experiments. The flexible connecting line was cleaned by washing with solvents and removing loose contaminations in the area of the laser riveting joints. This ensures a good contact of the copper surface of the flexible connecting line to the molybdenum rear contact.

Now the flexible connecting line and the solar cell are connected according to FIG. 3 d). In addition, a vacuum clamping device is used to press both metal surfaces together. After the molybdenum and the copper layer of the flexible connecting line are connected to each other according to FIG. 3 d), a single laser pulse of a duration of 10 ms and an energy of 0.15 J as well as a wavelength of 1064 nm is applied. The laser beam having a diameter of approx. 30 μm is focused on the drilled hole. Due to the energy of the laser beam, both the molybdenum and the copper layers are heated up to the melting or the vaporization point. Parts of the laser radiation have also passed through the hole down to the surface of the copper layer. Due to its low melting and vaporization temperature, the copper then melts and vaporizes. Parts of the molten copper pass through the hole due to the copper vapor pressure and build up around the laser-irradiated region. As the laser spot for riveting is larger than the hole drilled in the molybdenum layer, the molybdenum layer is heated up to melting point or even beyond the same. Subsequently, a stabile connection due to metallurgic processes and an interlocking of the metals after resolidification will result under participation of both molten metals. The transport of the molten copper of the small contact strip may also be supported by ablating or vaporizing the circuit board substrate, for example a polyimide film. Due to the generation of pressure during the ablation of this Kapton in particular, the entire molten copper will be hurled through the hole and can thus form the rivet.

Generally, it can be said for the inventive method that the materials of the thin-film substrate, the thin-film and the thin-film system, respectively, of the used laser and the kind, size, shape and distance of the openings are selected depending on the application under the aspects of electric bonding, electric conductivity, stability, reliability or manufacturing safety and efforts. The quantitative statements in particular as to materials, the general method steps and the preferred dimensions listed in connection with the description of the invention or the individual embodiments are not limited to these, but can analogously be transferred to the others, what can optionally be realized by the person skilled in the art. The invention is not limited to the embodiments. Modifications and combinations will become evident to the skilled person.

### LIST OF IDENTIFIERS

1 substrate of metal layer #1; backing film of the solar cell

2 metal layer #1; rear contact of the solar cell

3 semiconductor type 1; absorber layer of the solar cell; CIGS layer

4 semiconductor type 2; CdS layer

5 front side contact of the solar cell

6 metal layer #2; copper coating of the flexible electric connecting line

a) front side coating

b) rear side coating

7 substrate of metal layer #2; backing film of the flexible electric connecting line

8 opening of the backing film for exposing metal layer #1

9 bore in the metal layer #1

10 compressing force

11 compressing force

12 laser beam

13 laser rivet

14 scoring of the metal layer for electrical insulation

15 additionally applied metal layer; for bonding the front side to the insulated metal

16 current flow

1. A method for connecting thin metal layers, in particular the contact areas of thin-film solar cells, comprising:
by using a laser beam an opening is inserted in the backing film of a flexible thin-film solar cell, parts of the front contact and the absorber layer being removed and the thin-film rear contact being exposed,
an opening is inserted in the rear side of a thin-film solar cell by ablation using a pulsed UV laser,
wherein a destruction of the metal layer is excluded by selection of a short laser pulse duration,
the metal layers of the thin-film solar cell and a small contact strip are positioned facing each other,
the opening is pressed onto the small contact strip,
which consists of a backing film of a flexible electric connecting line having a copper coating,
the metals pressed onto each other are bonded by laser action,
for which laser beams having a pulse length of >1 μs are used,
the created thin-film solar cells may arbitrarily be connected in parallel or in series by using small contact strips.

2. The method for connecting thin metal layers according to claim 1, wherein a laser beam from the same source is used at a different energy.

3. The method for connecting thin metal layers according to claim 1, wherein
an Nd:YAG laser is used for connecting the two metal films, which ensures a wavelength of 1.06 μm.

4. The method for connecting thin metal layers according to claim 1, wherein
a plurality of rivet connections is placed.

5. The method for connecting thin metal layers according to claim 1, wherein the laser riveting process of a small contact strip and the thin-film solar cell is repeated a plurality of times in order to subsequently increase the solidity of the connection.

6. The method for connecting thin metal layers according to claim 1, wherein the removal of the upper layers by laser machining, mechanical scoring or masking is performed during the thin-film coat application after the positioning of the rear contact.

7. The method for connecting thin metal layers according to claim 1, wherein the pulsed laser radiation of the backing material of the solar cell is performed/carried out with the aim of removing it down to the rear contact, from a laser source having a wavelength in the range of 600 to 190 nm, a pulse duration of <10 μs and a spot size in the range of 5 to 500 μm.

8. The method for connecting thin metal layers according to claim 1, wherein for riveting the laser pulse has a pulse duration of >10 μs and a wavelength in the infrared or visible spectral range.

9. The method for connecting thin metal layers according to claim 1, wherein the drilling of the hole in the rear contact of the solar cell is performed/carried out by a pulsed laser having a pulse duration of <1 μs.

10. The method for connecting thin metal layers according to claim 1, wherein the laser beam is split into a plurality of partial beams for simultaneous laser treatment.

11. The method for connecting thin metal layers according to claim 1, wherein for drilling the hole in the rear contact the same laser is used as for the riveting process.

12. The method for connecting thin metal layers according to claim 1, wherein the temporary performance of the laser pulse is adjusted by mechanical, electro-optical or optical means.

13. A small contact strip consisting of a metal layer on a flexible substrate, suitable for micro riveting processes with a flexible thin-film solar cell.

14. The small contact strip according to claim 13, consisting of a copper layer on a polymer substrate.

15. The small contact strip according to claim 13, wherein it is a flexible circuit board for bonding a CIGS solar cell on a flexible polymer film.

16. The small contact strip according to claim 13, wherein the layer thickness of the metal layer of the small contact strip exceeds 2 μm.

17. The small contact strip according to claim 13, wherein the size of the micro rivets is in the range of 5 to 500 μm.

18. The small contact strip according to claim 13, wherein the micro rivets are arranged in a defined manner and the distance between the centers of the micro rivets is in the range of 1 to 10 times the size of the micro rivets.

19. The small contact strip according to claim 13, wherein the micro rivets are densely arranged in a row and form a slot/gap/longitudinal rivet.

20. The small contact strip according to claim 13, wherein it is fixed to a thin-film solar cell having a rear contact layer thickness of <5 μm.

21. The small contact strip according to claim 13, wherein it is pressed onto the thin-film solar cell by pressurized air.

22. A thin-film solar cell comprising a small contact strip stably connected by laser rivets.

23. (canceled)

24. (canceled)
